(19) United States
(12) Patent Application Publication
(10) Pub. No.: US 2019/0215970 A1
(43) Pub. Date: Jul. 11, 2019

(54) SURFACE MOUNTED CONTACT FINGERS

(71) Applicant: Intel Corporation, Santa Clara, CA (US)

(72) Inventor: Min-Tih Lai, Orangevale, CA (US)

(73) Assignee: Intel Corporation, Santa Clara, CA (US)

(21) Appl. No.: 16/315,292

(22) PCT Filed: Sep. 25, 2016
(86) PCT No.: PCT/US2016/053616

§ 371 Date: Jan. 4, 2019

(51) Int. Cl. H05K 3/40; H05K 1/11; H05K 3/28

(52) U.S. Cl. CPC H05K 3/4015; H05K 1/117; H05K 3/284; H05K 2203/1327; H05K 2201/1031; H05K 2203/1316; H05K 3/288

(57) ABSTRACT

Aspects of the embodiments are directed to an edge card assembled using surface mount technology (SMT). The edge card can be assembled by providing a printed circuit board comprising a first set of SMT pads proximate an edge of the printed circuit board to receive metal contact fingers and a second set of SMT pads to receive SMT components; placing a metal contact finger onto each of the first set of SMT pads; placing one or more SMT components onto at least some of the second set of SMT pads; providing a solder paste to the printed circuit board; and heating the printed circuit board to reflow the solder paste to mechanically and electrically connect the SMT components and the metal contact finger to the printed circuit board. The edge card can include a thin printed circuit board substrate.

### CROSS-REFERENCE TO RELATED APPLICATION

This application is a national stage application under 35 U.S.C. § 371 of PCT International Application Serial No. PCT/US2016/053616, filed on Sep. 25, 2016 and entitled “SURFACE MOUNTED CONTACT FINGERS,” which is hereby incorporated by reference herein in its entirety.

### TECHNICAL FIELD

This disclosure pertains to reducing printed circuit board dimensions, and more particularly, to the surface mounting of contact fingers onto a printed circuit board.

### BACKGROUND

Electronic devices need to provide more functionality at an ever shrinking form factor. Tablet and ultra-small (or ultra-thin) PCs require devices such as storage (SSD/HDD) and wireless modems (WiFi adaptor).

FIG. 1 is a schematic diagram of an example edge-card 100. The edge card has a “gum-stick” form factor. The “gum-stick” form factor edge-card connection allows for hardware swapping and upgrades, and has a thickness and X-Y footprint that takes up valuable real estate in the device. The example in FIG. 1 shows a basic “gum-stick” SSD card design 100 with components on one side. Components include an ASIC 102a, flash memory 102b-c, and passive components 104. Each of the three types of components (and the edge card connector itself) contribute to the X dimension of the card, and the total thickness (Z dimension) is defined by the thickest component plus the thickness of the card. Typically, the total Z dimension of the card (˜1 mm) with the flash packaging and other components (˜1 mm) is on the order of 2 mm.

### BRIEF DESCRIPTION OF THE DRAWINGS

FIG. 1 is a schematic diagram of an edge card having a gum-stick form factor.

FIG. 2 is a schematic diagram of an edge card having surface mounted contact fingers in accordance with embodiments of the present disclosure.

FIGS. 3A-D are schematic diagrams illustrating an example assembly procedure for forming edge cards in accordance with embodiments of the present disclosure.

FIG. 4 is a block diagram of an example computing device that may connected via a linear edge connector.

### DETAILED DESCRIPTION

This disclosure describes an edge card that can accommodate passive and active electronic components for providing computing and/or memory functionality. This disclosure describes using surface mount technology to place fingers that make up the Z-height requirement of edge card connectors, allowing for the rest of the device to be placed on a thin PCB substrate, thus reducing the Z (and by extension X and Y) dimension of the edge card. In embodiments, the metal contact fingers are placed using surface mount technology (SMT) techniques, similar to the placement of SMT components, thereby reducing the thickness of the card edge. SMT components can include flip-chip integrated circuit packages. SMT components can include application specific integrated circuits, processing circuits, memory, including flash memory circuit packages, as well as other circuit packages.

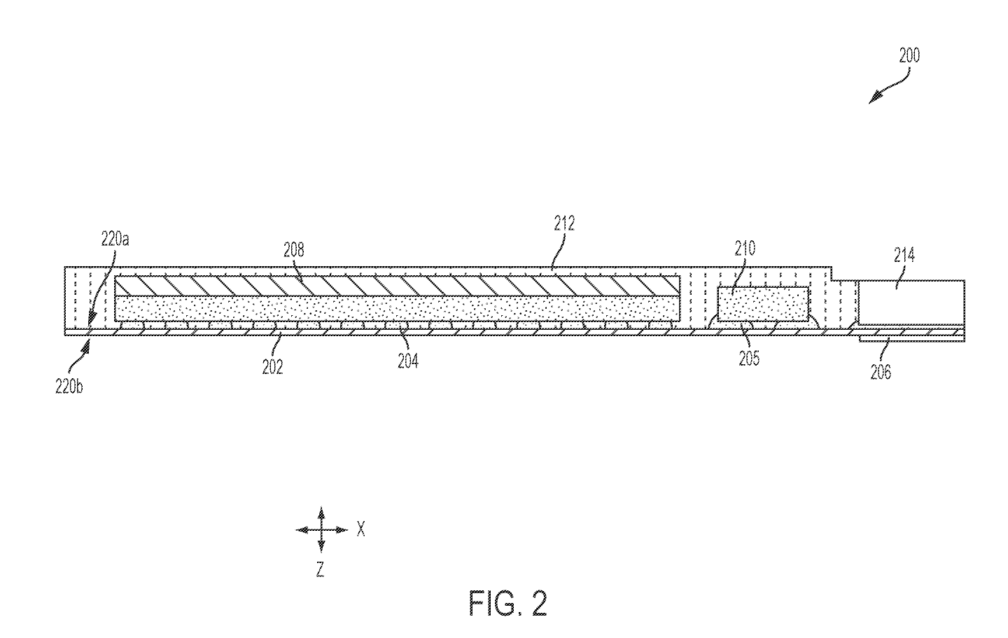

FIG. 2 is a schematic diagram of an edge card 200 having surface mounted contact fingers in accordance with embodiments of the present disclosure. The edge card 200 of FIG. 2 illustrates an edge card that has been manufactured using the techniques described herein. The edge card 200 includes a printed circuit board (PCB) 202, which can be a thin substrate style of PCB. The PCB 202 can include a plurality of solder balls 204 on a “top” side 220a of the PCB 202 that can electrically and mechanically connect the edge card components 208 to the PCB 202. In embodiments, the edge card components 208 can be stacked to reduce the size of the edge card 200 in the X and/or Y directions. Components 208 can be a flash card, ASIC, or other component, or can be a combination of components, such as components stacked on top of each other.

The PCB 202 can include a substrate that includes prepatterned vias for receiving metal electrodes to electrically connect one or more integrated circuit packages or one or more passive circuit elements residing on the PCB, or to electrically connect circuit components on the PCB 202 to metal contact fingers. The PCB 202 can also include prepatterned interconnects within the layering of the PCB 202 to interconnect circuit elements together, and to interconnect circuit elements to top-side and bottom-side metal contact fingers. The PCB 202 can be a single layer substrate or can include multiple layers. The PCB 202 can be made from different types of materials. For example, the PCB 202 can include a substrate composed of a glass fiber reinforced epoxy resin. In embodiments, the PCB 202 can include a substrate composed of a paper reinforced phenolic resin. Other types of PCB materials and layers and structures can be used without departing from the scope of this disclosure.

The PCB 202 can include pre-patterned metal contact fingers 206 on a “bottom” side 220b of the PCB 202 proximate to an edge of the edge card 200. On the top side 202a of the PCB 202, in a similar location to the pre-patterned metal contact fingers 206, a surface mount technology (SMT) pad can be formed to receive a plurality of metal fingers, which together form metal contact fingers on the top side 220a of the edge card 200. The shape and size of the metal fingers conforms to the corresponding connector into which the edge card 200 would fit.

The PCB 202 also includes one or more passive components 210 that are electrically and mechanically connected to the PCB 202 via solder balls 205.

The edge card 200 in FIG. 2 includes a thin PCB technology that allows the total Z dimension of the card, inclusive of the components, to be reduced (e.g., by on the order of 50%). Additionally, the edge card 200 and corresponding methods of manufacturing and assembly make it possible to make System in Package assemblies into edge card connectors by making changes to the parts, sub-assemblies, and components on a bill of materials and without using customized parts or methods of manufacturing or assembly. The edge card 200 can include an overmold 212 to add protection and rigidity to the edge card components. The overmold 212 can be processed, as described below, so that the metal fingers 214 that make up the contact fingers as well as the patterned metal contact finger 206 will fit into a corresponding receiver, such as a receiver with spring-mounted contacts that engage each metal finger on the edge card 200.

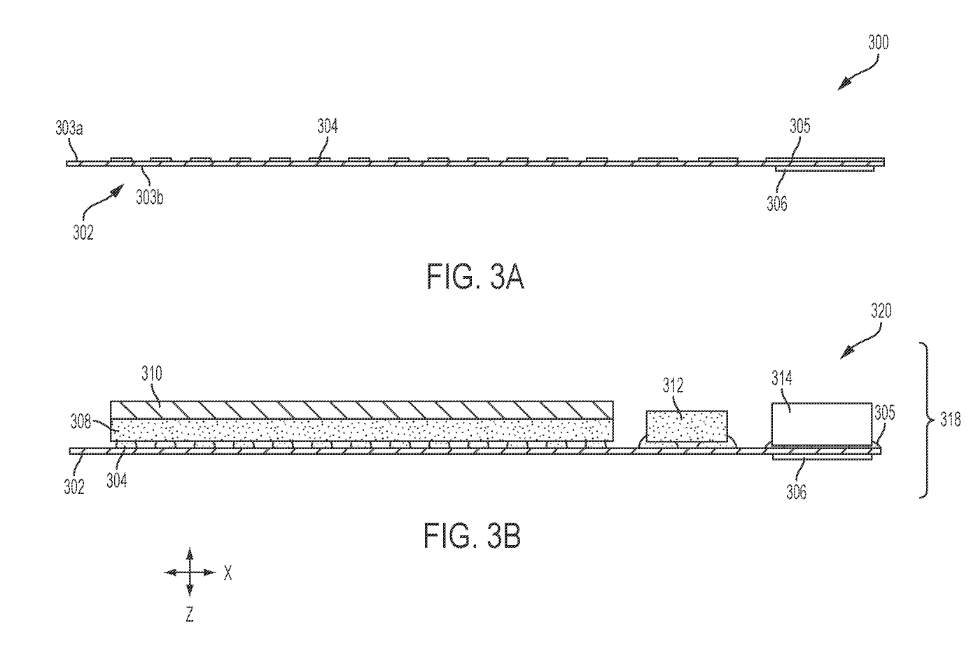

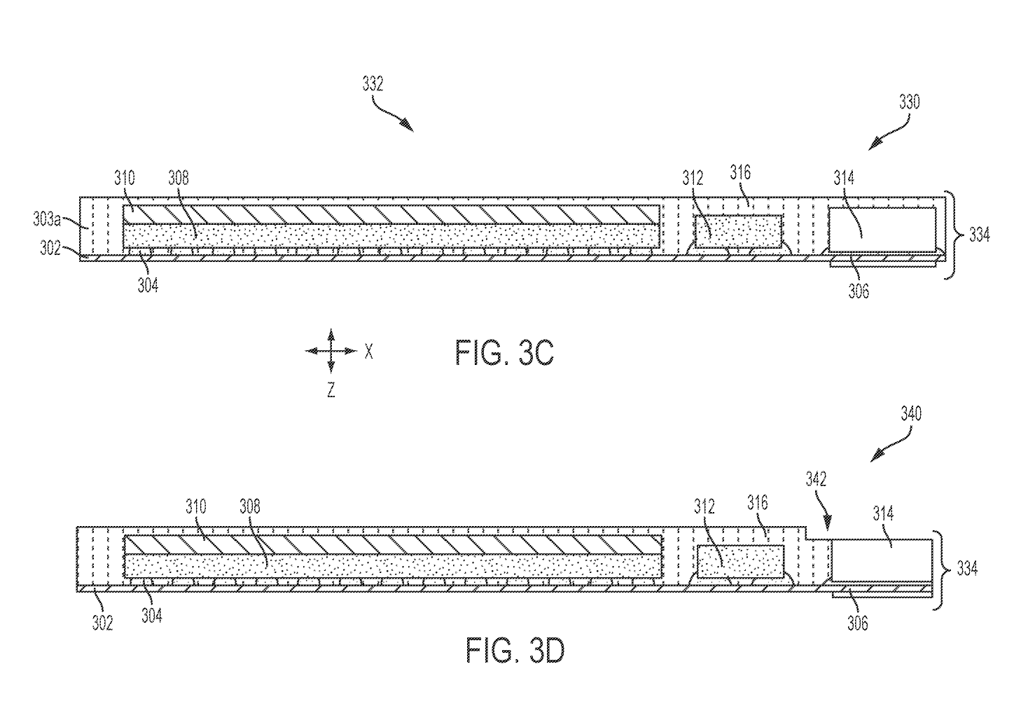

FIGS. 3A-D are schematic diagrams illustrating an example assembly procedure for forming edge cards in accordance with embodiments of the present disclosure. FIG. 3A illustrates a preliminary preparation stage 300 for PCB 302. In FIG. 3A, a thin PCB package substrate 302 can be pre-patterned on a bottom side 303b with metal fingers 306, while SMT pads 304 are formed on the top side 303a of the PCB 302. Metal fingers 306 can be any conducting metal for conducting electricity, such as copper, gold, or another metal used for interconnecting the edge card with an edge connector.

FIG. 3B illustrates an assembly step 320. In FIG. 3B, the surface mount technology (SMT) components, such as flash memory 308 and/or ASIC 310, as well as passive components 312, such as resistors, capacitors, etc., are placed first onto SMT pads 304. For example, the SMT components can be placed using an SMT or pick-and-place machine. The flash memory 308 and the ASIC 310 are shown to be stacked in FIG. 3B. Direct IC die bonding is also possible, including flip-chip, and die stacked wirebonds.

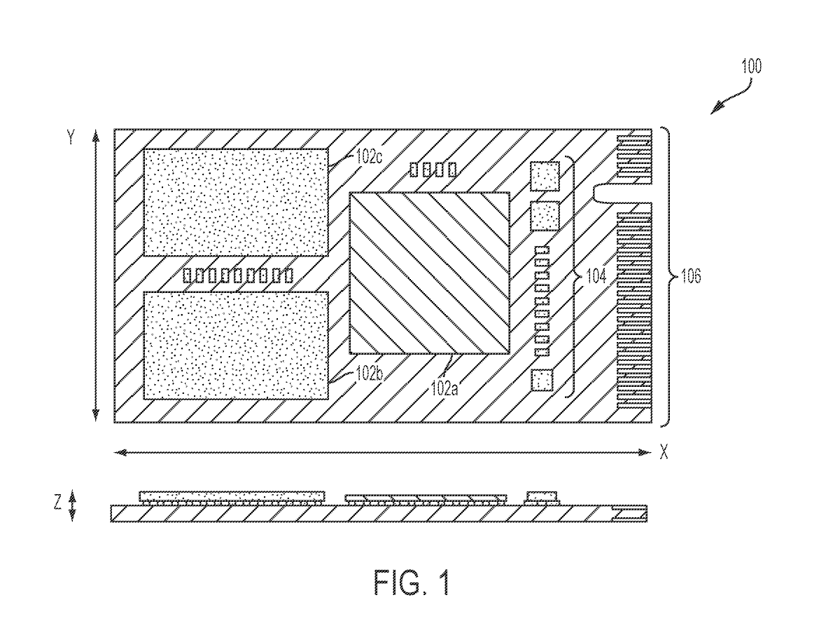

The metal contact fingers 314 can be placed onto the SMT pad 305 in a manner similar to the placement of the other SMT components, such as the flash memory 308, ASIC 310, or passive components 312, that are placed using the SMT or pick-and-place machine. Each metal contact finger 314 can be placed onto solder pad 305 on the top side 303a of the printed circuit board 302. Each metal contact finger 314 can be designed or selected to have a length, width, and height based on 1) a desired X and/or Y direction dimension of the printed circuit board (where X and Y are dimensions as indicated in FIGS. 1); and 2) the minimum required sizing to fit into an edge connector so that the edge card 318 can be electrically connected to the connector and mechanically connected to the connector (e.g., through spring mounted electrodes on the connector). Using the dimensions of FIG. 3B as an example, the total Z height of the edge card 318, including the printed circuit board, the SMT components, and metal contact fingers can be approximately 1.2 mm.

Solder is introduced, such as a solder paste, and the solder is reflowed through heating the PCB 302. The solder reflows to connect the SMT components 308, 310, and/or 312 and the metal contact fingers 314 to the PCB 302.

FIG. 3C illustrates an overmolding step 330. In embodiments, a mold chase presses down on the edge card strip (e.g., edge card strip 502 in FIG. 5) and liquid mold compound floods the top side of the edge card strip. When the liquid mold hardens, the resulting hardened mold 316 provides rigidity to the card (e.g., shown as 332 in FIG. 3C) and the edge connector 334.

FIG. 3D illustrates a singulation and grind back step 340. In embodiments, singulation of the edge card from the edge card strip creates an edge card having the metal contact fingers 314 and 306 at the edge of the edge card. The grind-back step exposes the fingers to the surface and conforms the edge of the card to the connector specifications. The grind back processes can remove excess overmolding from the edge of the edge card, and can also create a substantially flush surface for the edge connector. This grind-back is shown as a negative space 342, as well as by illustrating a flush edge for edge connector 334 from the pre-patterned metal contact 306 to the metal contact fingers 314. The fingers are exposed and are free to make electrical and mechanical contact with a connector.

In some embodiments, a mold chase specially designed to make contact solder fingers can be used to add the mold without covering the contact fingers; however, this would require a more specialized tooling.

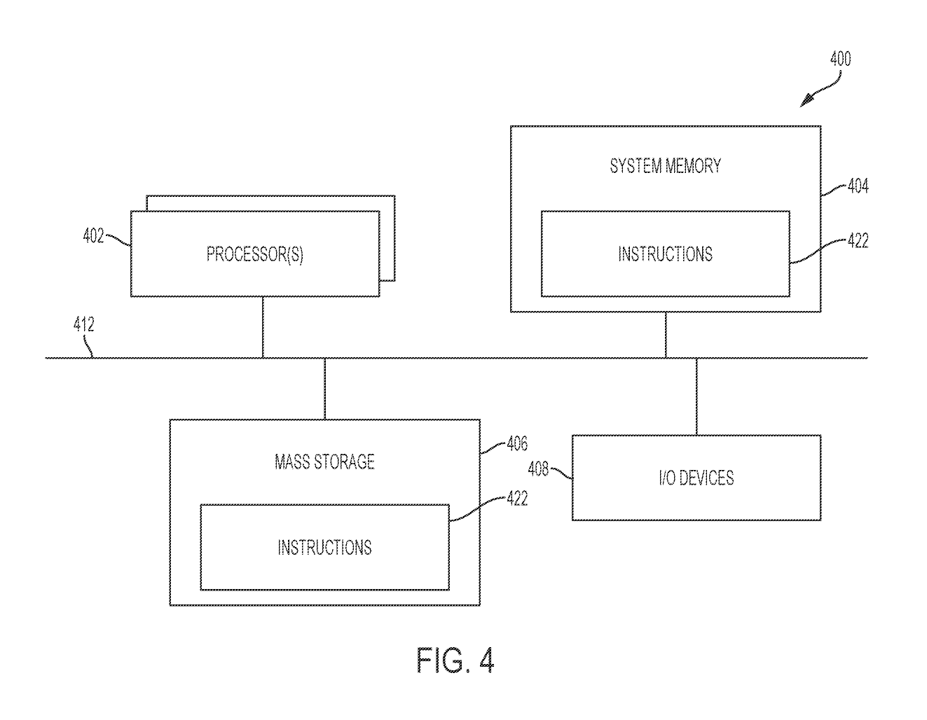

FIG. 4 is a block diagram of an example computing device 400 that may be connected via a linear edge connector. As shown, the computing device 400 may include one or more processors 402 (e.g., one or more processor cores implemented on one or more components) and a system memory 404 (implemented on one or more components). As used herein, the term “processor” or “processing device” may refer to any device or portion of a device that processes electronic data from registers and/or memory to transform that electronic data into other electronic data that may be stored in registers and/or memory. The processor(s) 402 may include one or more microprocessors, graphics processors, digital signal processors, crypto processors, or other suitable devices. More generally, the computing device 400 may include any suitable computational circuitry, such as one or more Application Specific Integrated Circuits (ASICs).

The computing device 400 may include one or more mass storage devices 406 (such as flash memory devices or any other mass storage device suitable for inclusion in a flexible IC package). The system memory 404 and the mass storage device 406 may include any suitable storage devices, such as volatile memory (e.g., dynamic random access memory (DRAM)), nonvolatile memory (e.g., read-only memory (ROM)), and flash memory. The computing device 400 may include one or more I/O devices 408 (such as display, user input device, network interface cards, modems, and so forth, suitable for inclusion in a flexible IC device). The elements may be coupled to each other via a system bus 412, which represents one or more buses.

Each of these elements may perform its conventional functions known in the art. In particular, the system memory 404 and the mass storage device 406 may be employed to store a working copy and a permanent copy of programming instructions 422.

The permanent copy of the programming instructions 422 may be placed into permanent mass storage devices 406 in the factory or through a communication device included in the I/O devices 408 (e.g., from a distribution server (not shown)). The constitution of elements 402-412 are known, and accordingly will not be further described.

The linear edge connectors disclosed herein can be used to couple any suitable computing devices, such as coupling the processor 402 to another device (e.g., a network device), processor,

Machine-accessible media (including non-transitory computer-readable storage media), methods, systems, and devices for performing the above-described techniques are illustrative examples of embodiments disclosed herein for a linear edge connector. For example, a computer-readable media (e.g., the system memory 404 and/or the mass storage device 406) may have stored thereon instructions (e.g., the instructions 422) such that, when the instructions are executed by one or more of the processors 402.

In various embodiments, the computing device 400 may be a laptop computer, a netbook computer, a notebook computer, an ultrabook computer, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 400 may be any other electronic device that processes data.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

The relative sizes of features shown in the figures are not drawn to scale.

The following paragraphs provide examples of various ones of the embodiments disclosed herein.

Example 1 is a method of manufacturing an edge card using surface mount technology (SMT), the method including providing a printed circuit board comprising a first set of SMT pads proximate an edge of the printed circuit board to receive metal contact fingers and a second set of SMT pads to receive SMT components; placing a metal contact finger onto each of the first set of SMT pads; placing one or more SMT components onto at least some of the second set of SMT pads; providing a solder paste to the printed circuit board; and heating the printed circuit board to reflow the solder paste to mechanically and electrically connect the SMT components and the metal contact finger to the printed circuit board.

Example 2 may include the subject matter of example 1, and can also placing one or more passive circuit components onto at least some of the second set of SMT pads prior to providing the solder paste.

Example 3 may include the subject matter of any of examples 1-2, and can also include forming an overmold on the printed circuit board.

Example 4 may include the subject matter of any of examples 1-3, wherein forming the overmold can include providing a liquid mold onto the printed circuit board; and curing the liquid mold to form an overmold on the printed circuit board, the overmold covering the metal contact finger and the one or more integrated circuit packages.

Example 5 may include the subject matter of any of examples 1-4, and can also include forming an overmold on the printed circuit board, wherein forming the overmold comprises placing a mold chase on a top side of the printed circuit board that covers the one or more integrated circuit packages to form an overmold over the integrated circuit packages and leaving exposed the metal contact fingers.

Example 6 may include the subject matter of any of examples 1-5, and can also include grinding the overmold to expose the metal contact fingers.

Example 7 may include the subject matter of any of examples 1-6, and can also include grinding the printed circuit board to create a flat edge on the printed circuit board and the metal contact fingers.

Example 8 may include the subject matter of any of examples 1-7, wherein the printed circuit board includes a thin printed circuit board substrate.

Example 9 may include the subject matter of any of examples 1-8, wherein placing one or more SMT components onto the printed circuit board on at least some of the SMT pads comprises placing at least one integrated circuit package onto the printed circuit board.

Example 10 may include the subject matter of any of examples 1-9, and can also include forming metal contact fingers on an underside of the printed circuit board.

Example 11 is an edge card that includes a printed circuit board comprising a first set of SMT pads proximate to an edge of the printed circuit board to receive metal contact fingers and a second set of SMT pads to receive SMT components; one or more SMT components placed onto at least some of the second set of SMT pads; and a metal contact finger placed onto each of the first set of SMT pads.

Example 12 may include the subject matter of example 11, wherein the metal contact finger has a height of substantially 1 millimeter.

Example 13 may include the subject matter of any of examples 11-12, and also include one or more passive circuit components mechanically and electrically connected to the printed circuit board strip via at least some of the SMT pads.

Example 14 may include the subject matter of any of examples 11-13, and also include an overmold on the printed circuit board.

Example 15 may include the subject matter of any of examples 11-14, wherein the overmold on the printed circuit board covers the one or more integrated circuits, and wherein the metal contact fingers are exposed.

Example 16 may include the subject matter of any of examples 11-15, wherein the printed circuit board includes a thin printed circuit board substrate.

Example 17 may include the subject matter of any of examples 11-16, wherein the one or more integrated circuit packages placed onto each of the printed circuit boards on at least some of the SMT pads are in a stacked configuration.

Example 18 may include the subject matter of any of examples 11-17, and also include a solder pad on an underside of the printed circuit board proximate to the central axis; and a plurality of metal contact fingers on the solder pad on the underside of the printed circuit board.

Example 19 is a printed circuit board that includes a first set of surface mount technology (SMT) pads proximate to an edge of the printed circuit board to receive metal contact fingers and a second set of SMT pads to receive SMT components; one or more SMT components placed onto at least some of the second set of SMT pads; and a plurality of metal contact fingers, each of the plurality of metal contact fingers placed onto each of the first set of SMT pads.

Example 20 may include the subject matter of example 19, wherein the metal contact finger has a height of substantially 1 millimeter.

Example 21 may include the subject matter of any of examples 19-20, and can also include one or more passive circuit components mechanically and electrically connected to the printed circuit board strip via at least some of the SMT pads.

Example 22 may include the subject matter of any of examples 19-21, and can also include an overmold on the printed circuit board.

Example 23 may include the subject matter of any of examples 19-22, wherein the overmold on the printed circuit board covers the one or more integrated circuits, and wherein the metal contact fingers are exposed.

Example 24 may include the subject matter of any of examples 19-23, wherein the first printed circuit board includes a thin printed circuit board substrate.

Example 25 may include the subject matter of any of examples 19-24 and also include a solder pad on an underside of the printed circuit board proximate to the central axis; and a plurality of metal contact fingers on the solder pad on the underside of the printed circuit board.

Example 26 is a computing device that includes a processor mounted on a substrate; a communications logic unit within the processor; a memory within the processor; a graphics processing unit within the computing device; an antenna within the computing device; a display on the computing device; a battery within the computing device; a power amplifier within the processor; and a voltage regulator within the processor. The computing device also includes an edge card. The edge card may include a printed circuit board comprising a first set of SMT pads proximate to an edge of the printed circuit board to receive metal contact fingers and a second set of SMT pads to receive SMT components; one or more SMT components placed onto at least some of the second set of SMT pads; and a metal contact finger placed onto each of the first set of SMT pads.

Example 27 may include the subject matter of example 26, wherein the metal contact finger comprises a height of substantially 1 millimeter.

Example 28 may include the subject matter of any of examples 26 or 27, and can also include one or more passive circuit components mechanically and electrically connected to the printed circuit board strip via at least some of the SMT pads.

Example 29 may include the subject matter of any of examples 26-28, and can also include an overmold on the printed circuit board.

Example 30 may include the subject matter of example 29, wherein the overmold on the printed circuit board covers the one or more integrated circuits, and wherein the metal contact fingers are exposed.

Example 31 may include the subject matter of any of examples 26-30, wherein the printed circuit board comprises a thin printed circuit board substrate.

Example 32 may include the subject matter of any of examples 26-31, wherein the one or more integrated circuit packages placed onto each of the printed circuit boards on at least some of the SMT pads are in a stacked configuration.

Example 33 may include the subject matter of any of examples 26-32, and can also include a solder pad on an underside of the printed circuit board proximate to the central axis; and a plurality of metal contact fingers on the solder pad on the underside of the printed circuit board.

Example 34 may include the subject matter of any of example 1-33, wherein the SMT components can include one or a combination of a flip chip integrated circuit package, such as an ASIC or a flash memory.

1-25. (canceled)

26. An edge card, comprising:
a printed circuit board having a first face, an opposing second face and an edge, wherein a first set of metal contact fingers is proximate to the edge at the first face, and wherein a set of surface mount pads is proximate to the edge at the second face; and
a second set of metal contact fingers coupled to the set of surface mount pads.

27. The edge card of claim 26, wherein the set of surface mount pads is a first set of surface mount pads, a second set of surface mount pads is at the second face, and one or more passive circuit components are coupled to the second set of surface mount pads.

28. The edge card of claim 26, wherein individual ones of the metal contact fingers in the second set of metal contact fingers have a height of approximately 1 millimeter.

29. The edge card of claim 26, further comprising:
a mold material on the printed circuit board.

30. The edge card of claim 29, wherein the metal contact fingers are not covered by the mold material.

31. The edge card of claim 29, further comprising:
one or more integrated circuit packages coupled to the second face of the printed circuit board.

32. The edge card of claim 31, wherein at least one of the one or more integrated circuit packages includes a stacked component.

33. The edge card of claim 32, wherein the stacked component includes a memory device and a processing device.

34. The edge card of claim 33, wherein the stacked component includes a Flash memory device and an application-specific integrated circuit (ASIC).

35. The edge card of claim 26, wherein the first set of metal contact fingers are printed on the first face of the printed circuit board.

36. An apparatus, comprising:
a printed circuit board, including:
a first set of conductive pads at a first face of the printed circuit board to couple to a first set of contact fingers,
a second set of conductive pads at the first face of the printed circuit board to couple to a set of electronic components, and
a second plurality of contact fingers patterned on a second face of the printed circuit board, wherein the second face is opposite to the first face.

37. The apparatus of claim 36, further comprising:
one or more electronic components coupled to the second set of conductive pads.

38. The apparatus of claim 37, wherein the one or more electronic components include a memory device.

39. The apparatus of claim 36, wherein the apparatus has a gumstick form factor.

40. The apparatus of claim 36, further comprising:
the first plurality of contact fingers, coupled to the first set of conductive pads via solder.

41. A method of manufacturing an edge card, comprising:
providing a printed circuit board comprising a first set of contact pads proximate an edge of the printed circuit board to receive metal contact fingers and a second set of contact pads to receive electronic components;
placing metal contact fingers onto at least some of the first set of contact pads; and
placing one or more electronic components onto at least some of the second set of contact pads.

42. The method of claim 41, further comprising:
placing one or more passive circuit components onto at least some of the second set of contact pads.

43. The method of claim 41, further comprising:
forming an overmold on the printed circuit board.

44. The method of claim 43, further comprising:
grinding the overmold to expose the metal contact fingers.

45. The method of claim 41, further comprising:
grinding the printed circuit board to create a flat edge on the printed circuit board and the metal contact fingers.
